(19) United States
(12) Patent Application Publication
(10) Pub. No.: US 2025/0113582 A1
(43) Pub. Date: Apr. 3, 2025

(54) SEMICONDUCTOR DEVICE

(71) Applicant: Hon Young Semiconductor Corporation, Hsinchu City (TW)

(72) Inventor: Chao-Yi CHANG, Hsinchu City (TW)

(21) Appl. No.: 18/430,672

(22) Filed: Feb. 2, 2024

(30) Foreign Application Priority Data
Oct. 2, 2023 (TW) 112137772

(51) Int. Cl. H01L 29/417; H01L 29/423

(52) U.S. Cl. CPC H10D 64/258; H10D 64/512; H10D 64/514; H10D 64/518

(57) ABSTRACT

A semiconductor device includes a drain electrode, a substrate, a first and a source contacts, a first and second gate electrodes, a gate connection structure and a gate insulation layer. The first and second source contacts are located on the substrate. The first and second gate electrodes are located between the first and second source contacts. The gate connection structure is located between the first and second gate electrodes and respectively connects the first gate electrode and the second gate electrode. The gate insulation layer surrounds the first and second gate electrodes, and the gate connection structure. The gate insulation layer includes an extension portion located between the first and second gate electrodes. An area of a vertical projection of the gate connection structure on the substrate is smaller than an area of a vertical projection of the extension portion of the gate insulation layer.

### CROSS-REFERENCE TO RELATED APPLICATION

This application claims priority to Taiwan Application Serial Number 112137772, filed Oct. 2, 2023, which is herein incorporated by reference in its entirety.

### BACKGROUND

### Field of Invention

The present invention relates to a semiconductor device.

### Description of Related Art

As the semiconductor technology progresses, metal oxide semiconductor FET is applied broadly. A power semiconductor can be used as a switch in an electronic device. The power semiconductor can be applied in a design having high voltage and high current. The switch rate and the on-resistance are highly related to the gate structure design.

### SUMMARY

One aspect of the present disclosure is a semiconductor device.

In one embodiment, a semiconductor device includes a drain electrode, a substrate located on the drain electrode, a first source contact and a second source contact located on the substrate, a first gate electrode and a second gate electrode located on the substrate and are located between the first source contact and the second source contact, a gate connection structure located between the first gate electrode and the second gate electrode and respectively connects the first gate electrode and the second gate electrode, and a gate insulation layer surrounding the first gate electrode, the second gate electrode, and the gate connection structure. The gate insulation layer includes an extension portion located between the first gate electrode and the second gate electrode, and an area of a vertical projection of the gate connection structure on the substrate is smaller than an area of a vertical projection of the extension portion of the gate insulation layer on the substrate.

Another aspect of the present disclosure is a semiconductor device.

In one embodiment, a semiconductor device includes a drain electrode, a substrate located on the drain electrode, wherein the substrate includes a top surface, a first source contact and a second source contact located on the substrate, a first gate electrode and a second gate electrode located on the substrate and are located between the first source contact and the second source contact, a gate connection structure located between the first gate electrode and the second gate electrode and respectively connects the first gate electrode and the second gate electrode, and a dielectric layer located between the gate connection structure and the substrate. The first gate electrode includes a first bottom surface facing the substrate, and the gate connection structure includes a second bottom surface in contact with the dielectric layer. A first distance between the first bottom surface and the top surface of the substrate is smaller than a second distance between the second bottom surface and the top surface of the substrate.

In aforementioned embodiments, an overlapping area between the gate connection structure and the drain electrode along a vertical direction is reduced by connecting the first gate electrode and the second gate electrode through the gate connection structure, and the capacitance between the gate and the drain is reduced to improve switch rate and the stability during the switch process. In addition, layout of the gate electrodes is compact, channel density per unit area of the semiconductor device is increased, and the current density is increased to reduce the Drain-source on-state resistance.

### BRIEF DESCRIPTION OF THE DRAWINGS

The invention can be more fully understood by reading the following detailed description of the embodiment, with reference made to the accompanying drawings as follows:

FIG. 1 is a perspective view of a semiconductor device according to one embodiment of the present disclosure.

FIG. 2 is a top view of the semiconductor device in FIG. 1.

FIG. 3 is a top view of a semiconductor device according to one embodiment of the present disclosure.

FIG. 4A is a perspective view of a semiconductor device according to one embodiment of the present disclosure.

FIG. 4B is a cross-sectional view taken along the line 4B-4B in FIG. 4A.

FIG. 5A is a perspective view of a semiconductor device according to one embodiment of the present disclosure.

FIG. 5B is a top view of the semiconductor device in FIG. 5A.

FIG. 6 is a top view of a semiconductor device according to one embodiment of the present disclosure.

FIG. 7 is a perspective view of a semiconductor device according to one embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

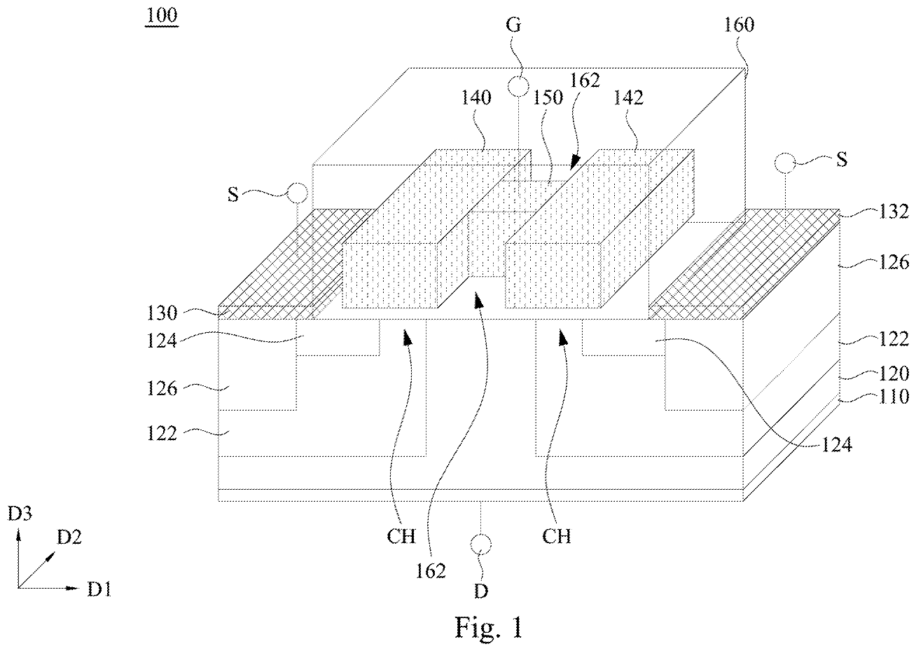

FIG. 1 is a perspective view of a semiconductor device 100 according to one embodiment of the present disclosure. The semiconductor device 100 includes a drain electrode 110, a substrate 120, a first source contact 130, a second source contact 132, a first gate electrode 140, a second gate electrode 142, a gate connection structure 150, and a gate insulation layer 160, which form a source S, a drain D, and a gate G of the semiconductor device 100. The first gate electrode 140 and the second gate electrode 142 are connected through the gate connection structure 150 to provide same voltage.

The substrate 120 is located on the drain electrode 110. The first source contact 130 and the second source contact 132 are located on the substrate 120. The first gate electrode 140 and the second gate electrode 142 are located on the substrate 120 and are located between the first source contact 130 and the second source contact 132. The gate connection structure 150 is located between the first gate electrode 140 and the second gate electrode 142. The gate insulation layer 160 surrounds the first gate electrode 140, the second gate electrode 142, and the gate connection structure 150.

The materials of the first gate electrode 140, the second gate electrode 142, and the gate connection structure 150 include conductive materials such as poly-silicon, W, WSi, Ti, TIN, Ni, NixSiy, etc.

For example, the semiconductor device 100 of the present disclosure is an n-type (first conductive type) metal oxide semiconductor field effect transistor. The substrate 120 has the first conductive type (n-type). The substrate 120 is a heavily doped substrate (N+). The substrate 120 further includes epitaxy layers, and the doping concentration of the epitaxy layers (N−) is lower than a doping concentration of the substrate 120. The epitaxy layer forms a shift region of the source S and the drain D.

The semiconductor device 100 further includes a doping well 122, a source doping region 124, and a contact doping region 126. The doping well 122 is a p-type doping region (second conductive type), and the source doping region 124 is an n-type doping region. The source doping region 124 and the contact doping region 126 are located in the doping well 122. The contact doping region 126 is a p-type heavily doped region (P+). The p-type doping well 122 and the n-type source doping region 124 form a channel region CH therebetween.

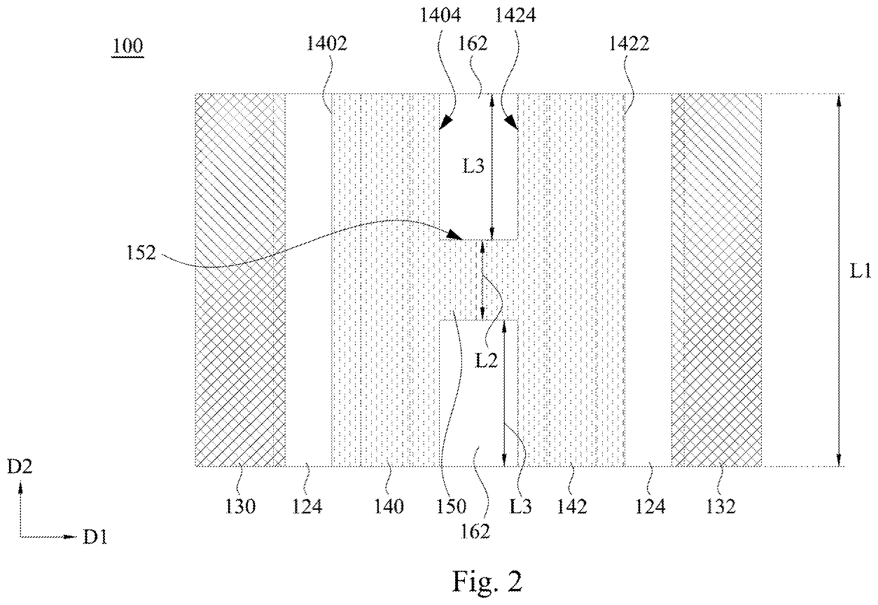

FIG. 2 is a top view of the semiconductor device 100 in FIG. 1. The gate insulation layer 160 includes an extension portion 162 located between the first gate electrode 140 and the second gate electrode 142. That is, the extension portion 162 fills the space between the first gate electrode 140 and the second gate electrode 142.

As shown in FIG. 1 and FIG. 2, the first gate electrode 140, the gate connection structure 150, and the second gate electrode 142 are arranged along a first direction D1. The first gate electrode 140 and the second gate electrode 142 extend along a second direction D2. The first direction D1 of the present embodiment is perpendicular to the second direction D2 in the present embodiment. The first gate electrode 140 and the second gate electrode 142 have a first length L1 along the second direction D2. The gate connection structure 150 has a second length L2 along the second direction D2. The first length L1 is greater than the second length L2. An area of a vertical projection of the gate connection structure 150 on the substrate 120 is smaller than an area of a vertical projection of the extension portion 162 of the gate insulation layer 160 one the substrate 120.

It is noted that the gate connection structure 150 of the present disclosure is not extend from the first gate electrode 140 to the second gate electrode 142. On the contrary, the first gate electrode 140 and the second gate electrode 142 are merely connected through the gate connection structure 150 having a smaller volume. As such, an overlapping area between the gate connection structure 150 and the drain electrode 110 along a vertical direction D3 is reduced, and the capacitance between the gate G and the drain D is reduced to improve switch rate and the stability during the switch process.

In the present embodiment, the first gate electrode 140 and the second gate electrode 142 have strip shape. The gate connection structure 150, the first gate electrode 140, and the second gate electrode 142 form a H shape structure. The second length L2 of the gate connection structure 150 along the second direction D2 is smaller than a third length L3 of the extension portion 162 of the gate insulation layer 160 along the second direction D2.

As shown in FIG. 2, a vertical projection of the gate connection structure 150 on the drain electrode 110 is substantially located between vertical projections of two doping wells 122 on the drain electrode 110. In other words, as long as the property of the channel region CH is not affected by the areas of the first gate electrode 140 and the second gate electrode 142, the volume of the gate connection structure 150 can be reduced as much as possible.

The first gate electrode 140 has a first inner wall 1402 and a first outer wall 1404. The first inner wall 1402 is proximate to the first source contact 130, and the first outer wall 1404 is proximate to the second gate electrode 142. The second gate electrode 142 has a second inner wall 1422 and a second outer wall 1424. The second inner wall 1422 is proximate to the second source contact 132, and the second outer wall 1424 is proximate to the first gate electrode 140.

The gate connection structure 150 has a side wall 152 connected with the first outer wall 1404 and the second outer wall 1424. The shape of the gate connection structure 150 is substantially rectangular. Therefore, the side wall 152 is perpendicular to the first outer wall 1404 and the second outer wall 1424. In other embodiments, the gate connection structure 150 has arbitrary shape such as circular shape, oval shape, polygon, or irregular shape.

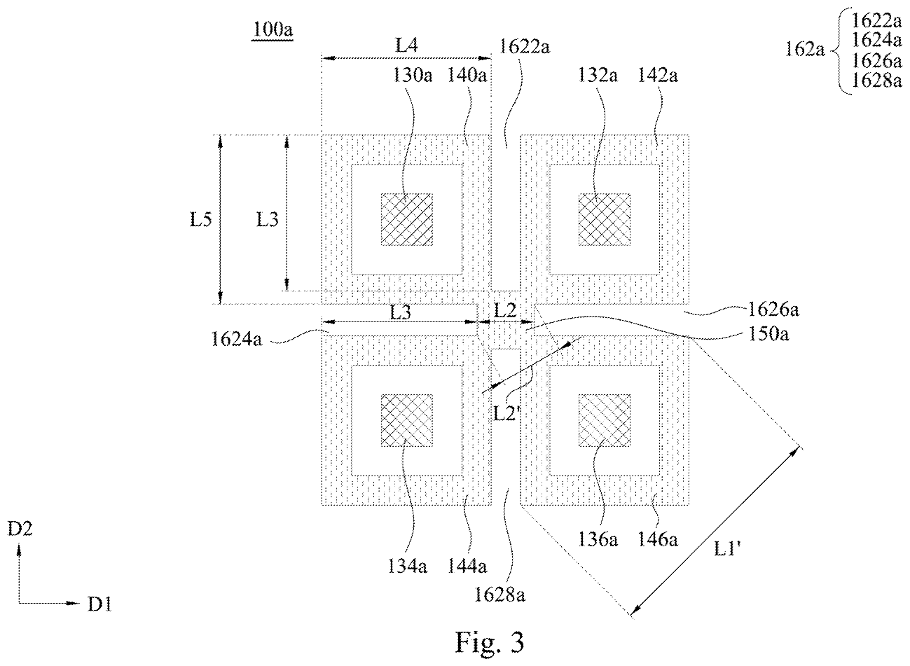

FIG. 3 is a top view of a semiconductor device 100a according to one embodiment of the present disclosure. In a top view, the first gate electrode 140a and the second gate electrode 142a respectively surround the first source contact 130a and the second source contact 132a from a lateral side. Therefore, the first gate electrode 140a and the second gate electrode 142a both have a hollow ring shape in a plan view.

The semiconductor device 100a further includes a third source contact 134a, a fourth source contact 136a, a third gate electrode 144a, and a fourth gate electrode 146a. The third gate electrode 144a surrounds the third source contact 134a, and the fourth gate electrode 146a surrounds the fourth source contact 136a.

The gate connection structure 150a is located at corners of the first gate electrode 140a, the second gate electrode 142a, the third gate electrode 144a, and the fourth gate electrode 146a facing each other, and therefore the gate connection structure 150a can connect four gate electrodes simultaneously.

In the embodiment in FIG. 3, the shapes of the first gate electrode 140a, the second gate electrode 142a, the third gate electrode 144a, and the fourth gate electrode 146a are the same or correlate with the shapes of the first source contact 130a, the second source contact 132a, the third source contact 134a, and the fourth source contact 136a, which are square shapes. In some embodiments, other shapes can be used such as circular shape, rectangular shape, diamond shape, triangular shape, equilateral polygon, or inequilateral polygon. In some embodiments, more than four gate electrodes and source contacts can be disposed, and more than two gate connection structures can be used to connect the corners or sides of those gate electrodes.

In the present embodiment, an extension portion 162a of the gate insulation layer 160a includes a first part 1622a, a second part 1624a, a third part 1626a, and a fourth part 1628a respectively located between the first gate electrode 140a and the second gate electrode 142a, between the first gate electrode 140a and the third gate electrode 144a, between the second gate electrode 142a and the fourth gate electrode 146a, and between the third gate electrode 144a and the fourth gate electrode 146a.

In the present embodiment, multiple gate electrodes are arranged along the first direction D1 and the second direction D2. Each of the gate electrodes includes sections extending along the first direction D1 and the second direction D2. For example, a section of the first gate electrode 140a extending along the first direction D1 has a fourth length L4, and the fourth length L4 is greater than the second length L2 of the gate connection structure 150a. A section of the first gate electrode 140a extending along the second direction D2 has a fifth length L5, and the fifth length L5 is greater than the second length L2 of the gate connection structure 150a. The third length L3 of the extension portion 162a of the gate insulation layer 160a is greater than the second length L2 of the gate connection structure 150a.

With aforementioned structure design, adjacent two of the gate electrodes are mostly separated by the extension portion 162a of the gate insulation layer 160a, such that the volume and the area of the gate connection structure 150a only consumes a small portion. As such, layout of the gate electrodes is compact, channel density per unit area of the semiconductor device 100a is increased, and the current density is increased to reduce the Drain-source on-state resistance.

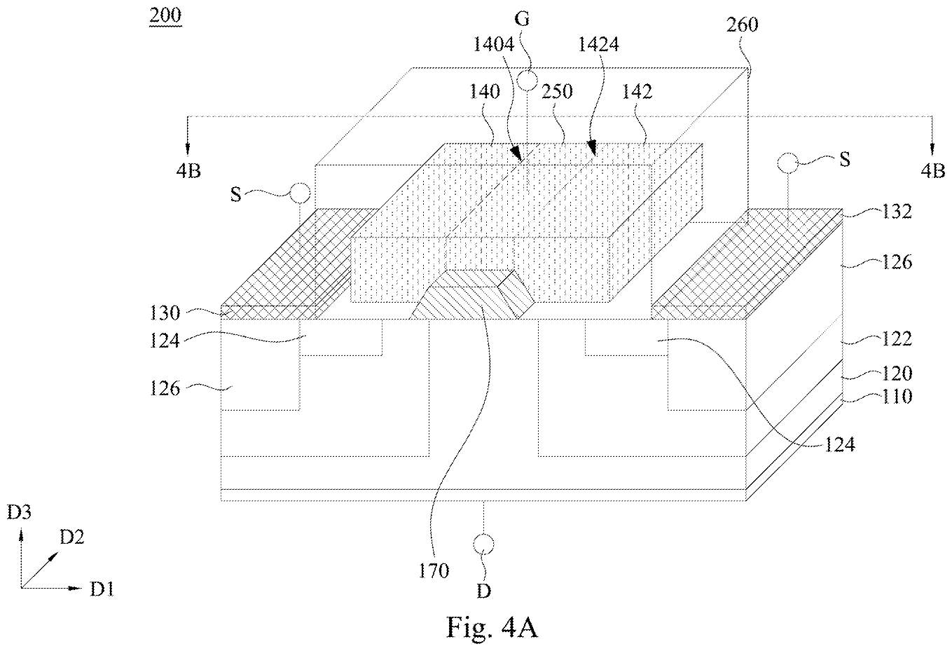

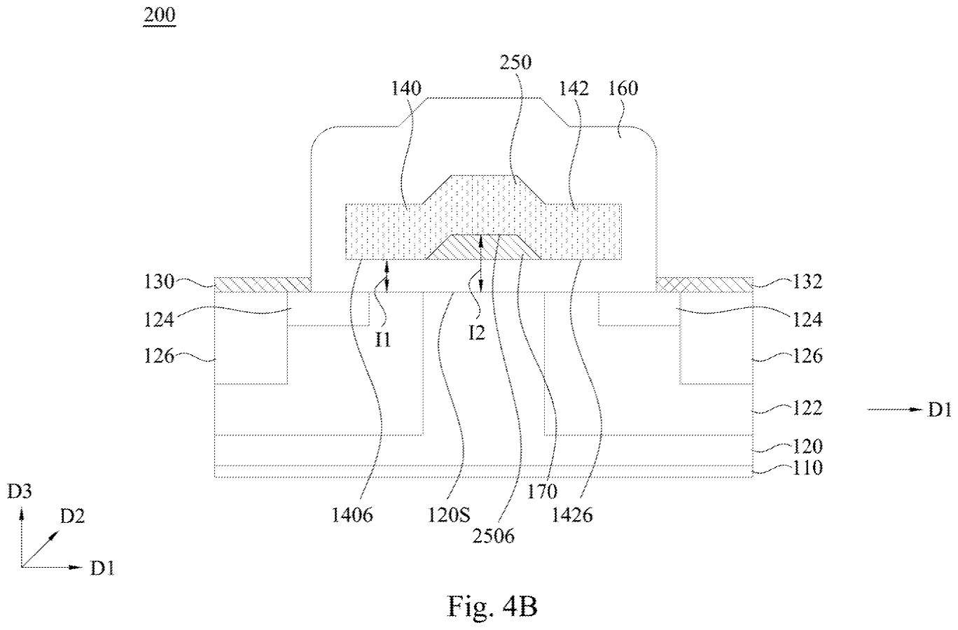

FIG. 4A is a perspective view of a semiconductor device 200 according to one embodiment of the present disclosure. FIG. 4B is a cross-sectional view taken along the line 4B-4B in FIG. 4A. The semiconductor device 200 is similar to the semiconductor device 100 in FIG. 1, and the difference is that the semiconductor device 200 includes a dielectric layer 170 located between the substrate 120 and the gate connection structure 250 and located between the first gate electrode 140 and the second gate electrode 142. A gate connection structure 250 connects the entire first outer wall 1404 of the first gate electrode 140 and the entire second outer wall 1424 of the second gate electrode 142.

The first gate electrode 140 has a first bottom surface 1406 facing the substrate 120, the gate connection structure 250 has a second bottom face 2506 in contact with the dielectric layer 170. The second gate electrode 142 has a third bottom surface 1426 facing the substrate 120. The first bottom surface 1406 and the top surface 120S of the substrate 120 have a first distance 11 therebetween, and the second bottom face 2506 and the top surface 120S of the substrate 120 have a second distance 12 therebetween. The first distance 11 is smaller than the second distance 12. In other words, the distance from the gate connection structure 250 to the substrate 120 and the drain electrode 110 can be increased through the dielectric layer 170. As such, capacitance between the gate G and the drain D is reduced to improve switch rate and the stability during the switch process.

An area of a vertical projection of the dielectric layer 170 on the drain electrode 110 is greater than an area of a vertical projection of the gate connection structure 250 on the drain electrode 110, or as long as the dielectric layer 170 at least elevates the gate connection structure 250 along the vertical direction D3. The gate insulation layer 160 surrounds the first gate electrode 140, the second gate electrode 142, the gate connection structure 250, and the dielectric layer 170.

A length ratio or a width ratio between the dielectric layer 170 and the first gate electrode 140 and between the second gate electrode 142 and the gate connection structure 250 can be different. A thickness and an inclined angle of the dielectric layer 170 are not limited to the configurations shown in FIG. 4A. The material of the dielectric layer includes insulating materials such as SiO2, USG, Boro-silicate Glass, BSG, phospho-silicate Glass (PSG), Boro-phospho-silicate Glass (BPSG), high-k material, SiN, Oxynitride. The material of the dielectric layer 170 and the gate insulation layer 160 can be the same or different.

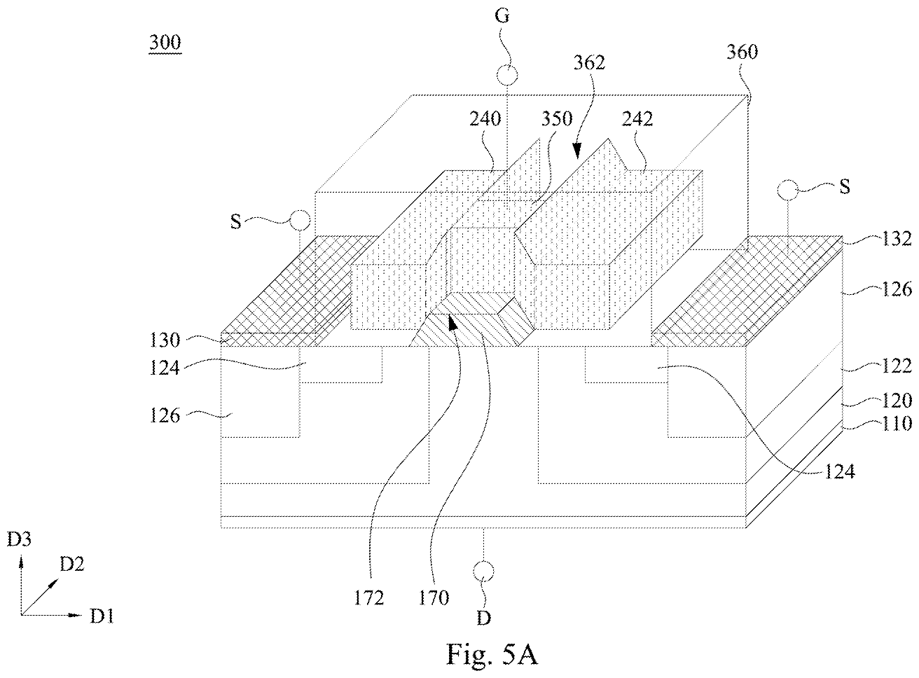

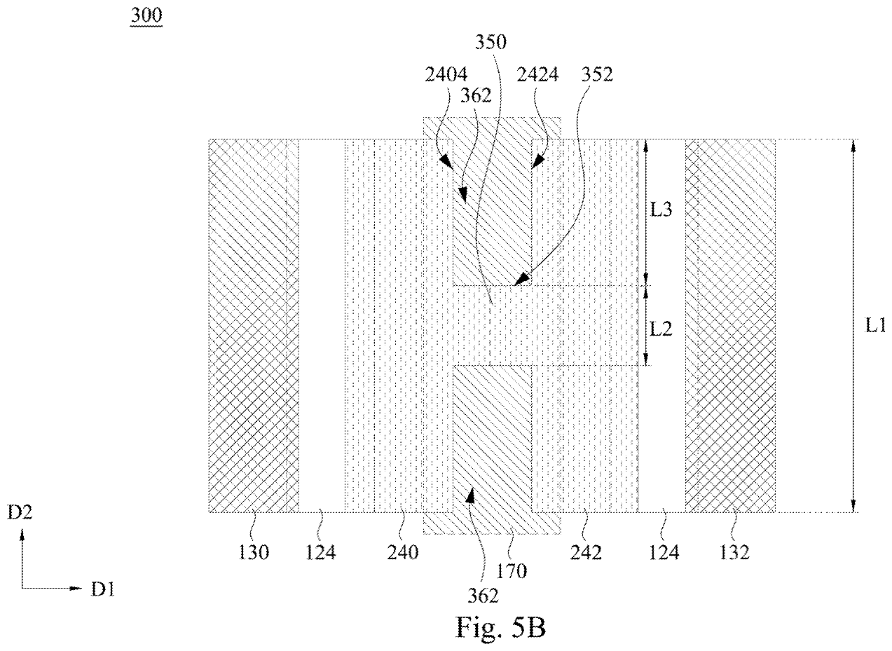

FIG. 5A is a perspective view of a semiconductor device 300 according to one embodiment of the present disclosure. FIG. 5B is a top view of the semiconductor device in FIG. 5A. The semiconductor device 300 is similar to the semiconductor device 200 in FIG. 4A, and the difference is that the gate connection structure 350 of the semiconductor device 300 is the same as the gate connection structure 150 in FIG. 1. The second length L2 of the gate connection structure 350 is smaller than the first length L1 of the first gate electrode 240 and the second gate electrode 242. The second length L2 of the gate connection structure 350 is smaller than the third length L3 of the extension portion 362 of the gate insulation layer 360. As such, an overlapping area between the gate connection structure 350 and the drain electrode 110 along the vertical direction D3 is reduced, and the capacitance between the gate G and the drain D is reduced to improve switch rate and the stability during the switch process.

The top surface 172 of the dielectric layer 170 is partially exposed from the gate connection structure 350. The extension portion 362 is collectively surrounded by the first outer wall 2404, the second outer wall 2424, the top surface 172, and the side wall 352. The structural relation between the dielectric layer 170 and the gate connection structure 350 is the same as that shown in FIG. 4B. Therefore, the gate connection structure 350 can be further away from the substrate 120 and the drain electrode 110 by the dielectric layer 170, and the capacitance between the gate G and the drain D is reduced to improve switch rate and the stability during the switch process.

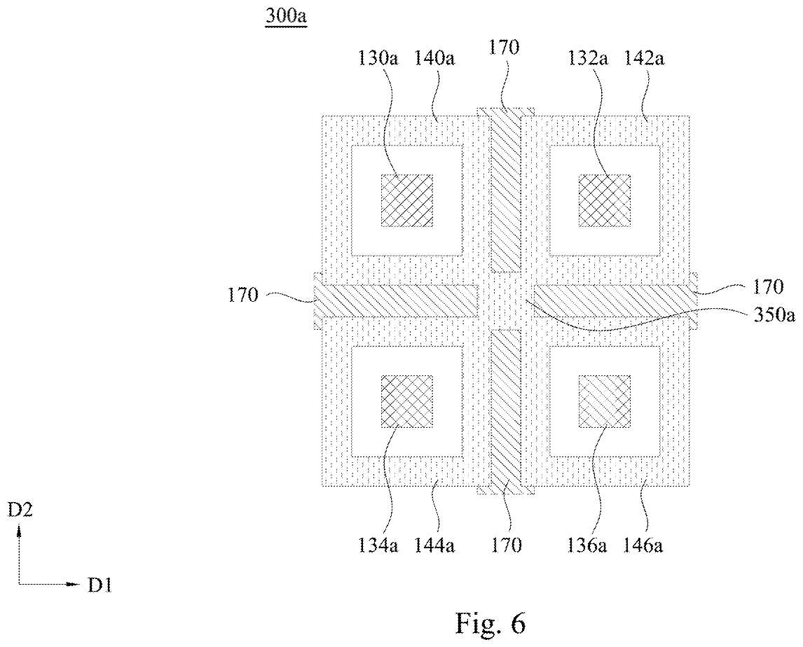

FIG. 6 is a top view of a semiconductor device 300a according to one embodiment of the present disclosure. The semiconductor device 300a is similar to the semiconductor device 100a in FIG. 3, and the difference is that the semiconductor device 300a further includes the dielectric layer 170 shown in FIG. 5A. The dielectric layer 170 surrounds the first gate electrode 140a, the second gate electrode 142a, the third gate electrode 144a, and the fourth gate electrode 146a when the four gate electrodes in FIG. 6 are arranged repeatedly. The semiconductor device 300a has the same advantages as the semiconductor device 100a in FIG. 3 and the semiconductor device 300 in FIG. 5A, and therefore the description is not repeated hereinafter.

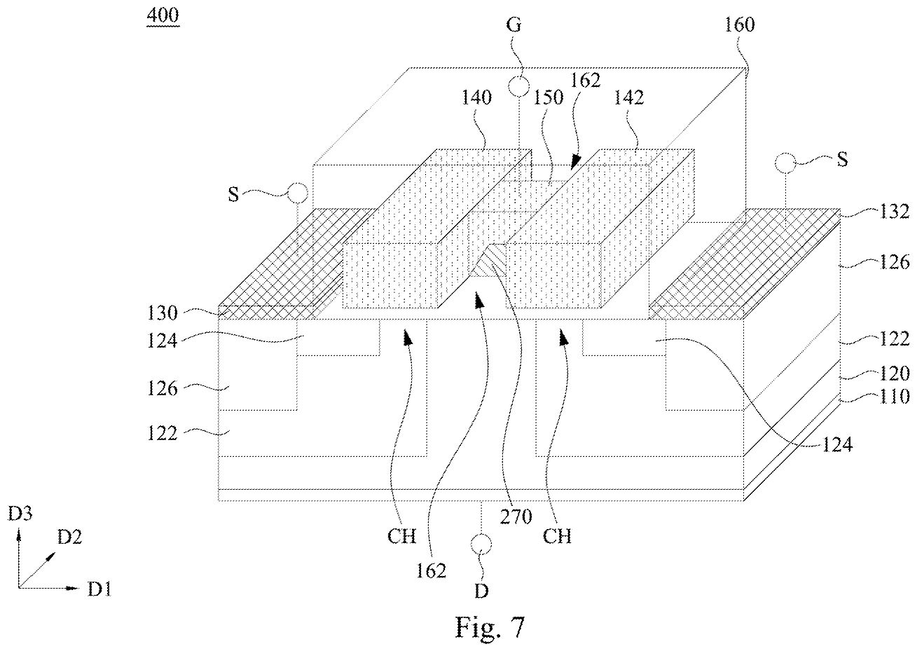

FIG. 7 is a perspective view of a semiconductor device 400 according to one embodiment of the present disclosure. The semiconductor device 400 is similar to the semiconductor device 100 in FIG. 1, and the difference is that the semiconductor device 400 further includes a dielectric layer 270 between the gate connection structure 150 and the substrate 120. An area of a vertical projection of the dielectric layer 270 on the drain electrode 110 is substantially the same as an area of a vertical projection of the gate connection structure 150 on the drain electrode 110. The dielectric layer 270 can be applied in the embodiment in FIG. 6 as long as the gate connection structure 150 can be elevated by the dielectric layer 170 along the vertical direction D3.

In summary, a gate connection structure of the present disclosure is used to connect a first gate electrode and a second gate electrode disposed adjacently. In addition, an area of a vertical projection of the gate connection structure on the substrate is smaller than an area of a vertical projection of the extension portion of the gate insulation layer on the substrate. In other words, the first gate electrode and the second gate electrode are merely connected through the gate connection structure having a smaller volume. As such, an overlapping area between the gate connection structure and the drain electrode along a vertical direction is reduced, and the capacitance between the gate and the drain is reduced to improve switch rate and the stability during the switch process. In addition, layout of the gate electrodes is compact, channel density per unit area of the semiconductor device is increased, and the current density is increased to reduce the Drain-source on-state resistance. In some embodiment, the distance from the gate connection structure to the substrate and the drain electrode can be increased through the dielectric layer which is located between the gate connection structure and the substrate. As such, capacitance between the gate and the drain is reduced to improve switch rate and the stability during the switch process.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A semiconductor device, comprising:
a drain electrode;
a substrate located on the drain electrode;
a first source contact and a second source contact located on the substrate;
a first gate electrode and a second gate electrode located on the substrate and are located between the first source contact and the second source contact;
a gate connection structure located between the first gate electrode and the second gate electrode and respectively connecting the first gate electrode and the second gate electrode; and
a gate insulation layer surrounding the first gate electrode, the second gate electrode, and the gate connection structure, wherein the gate insulation layer comprises an extension portion located between the first gate electrode and the second gate electrode, and an area of a vertical projection of the gate connection structure on the substrate is smaller than an area of a vertical projection of the extension portion of the gate insulation layer on the substrate.

2. The semiconductor device of claim 1, wherein the first gate electrode, the gate connection structure, and the second gate electrode are arranged along a first direction, the first gate electrode and the second gate electrode extend along a second direction, and a first length of the first gate electrode and the second gate electrode along the second direction is greater than a second length of the gate connection structure along the second direction.

3. The semiconductor device of claim 2, wherein the first gate electrode and the second gate electrode have a strip shape, and a second length of the gate connection structure along the second direction is smaller than a third length of the extension portion of the gate insulation layer along the second direction.

4. The semiconductor device of claim 1, wherein the first gate electrode and the second gate electrode surround the first source contact and the second source contact from a lateral side respectively.

5. The semiconductor device of claim 4, further comprises a third source contact and a third gate electrode, the third gate electrode surrounds the third source contact, and the gate connection structure connects the third gate electrode.

6. The semiconductor device of claim 5, wherein the first gate electrode, the second gate electrode, and the third gate electrode have polygon shape, and a number of sides of the polygon is greater than or equals three.

7. The semiconductor device of claim 5, wherein the extension portion of the gate insulation layer comprises a first part and a second part, the first part is located between the first gate electrode and the second gate electrode, the second part is located between the first gate electrode and the third gate electrode, and the gate connection structure is located between the first part and the second part.

8. The semiconductor device of claim 1, further comprising:
a dielectric layer located between the substrate and the gate connection structure and located between the first gate electrode and the second gate electrode.

9. The semiconductor device of claim 1, wherein the first gate electrode comprises a first outer wall, the second gate electrode comprises a second outer wall, the gate connection structure comprises a side wall, the first outer wall faces the second outer wall, and the side wall connects the first outer wall and the second outer wall.

10. A semiconductor device, comprising:
a drain electrode;
a substrate located on the drain electrode, wherein the substrate comprises a top surface;
a first source contact and a second source contact located on the substrate;
a first gate electrode and a second gate electrode located on the substrate and are located between the first source contact and the second source contact;
a gate connection structure located between the first gate electrode and the second gate electrode and respectively connecting the first gate electrode and the second gate electrode; and
a dielectric layer located between the gate connection structure and the substrate, wherein the first gate electrode comprises a first bottom surface facing the substrate, the gate connection structure comprises a second bottom surface in contact with the dielectric layer, a first distance between the first bottom surface and the top surface of the substrate is smaller than a second distance between the second bottom surface and the top surface of the substrate.

11. The semiconductor device of claim 10, wherein an area of a vertical projection of the dielectric layer on the drain electrode is greater than an area of a vertical projection of the gate connection structure on the drain electrode.

12. The semiconductor device of claim 10, wherein an area of a vertical projection of the dielectric layer on the drain electrode equals an area of a vertical projection of the gate connection structure on the drain electrode.

13. The semiconductor device of claim 10, further comprising a gate insulation layer surrounding the first gate electrode, the second gate electrode, the gate connection structure, and the dielectric layer.

14. The semiconductor device of claim 13, wherein a material of the gate insulation layer is different form a material of the dielectric layer.

15. The semiconductor device of claim 10, wherein first gate electrode and the second gate electrode surround the first source contact and the second source contact from a lateral side respectively, and the dielectric layer surrounds the first gate electrode and the second gate electrode from the lateral side.
